(19) United States
(12) Patent Application Publication
(10) Pub. No.: US 2021/0141983 A1
(43) Pub. Date: May 13, 2021

(54) PROCESSING APPARATUS, METHOD OF DETECTING A FEATURE PART OF A CAD MODEL, AND NON-TRANSITORY COMPUTER READABLE MEDIUM STORING A PROGRAM

(71) Applicant: JAPAN AEROSPACE EXPLORATION AGENCY, Tokyo (JP)

(72) Inventors: Masashi KANAMORI, Tokyo (JP); Takashi ISHIDA, Tokyo (JP); Atsushi HASHIMOTO, Tokyo (JP); Takashi AOYAMA, Tokyo (JP)

(21) Appl. No.: 17/043,402

(22) PCT Filed: Apr. 1, 2019
(86) PCT No.: PCT/JP2019/014428

§ 371 Date: Sep. 29, 2020

(30) Foreign Application Priority Data
Apr. 3, 2018 (JP) 2018-071823

(51) Int. Cl. G06F 30/23; G06F 30/25; G06F 30/15; G06T 17/20

(52) U.S. Cl. CPC G06F 30/23; G06F 30/25; G06T 2210/56; G06T 17/20; G06F 30/15

(57) ABSTRACT

[Object] To appropriately make apparent the feature part of the object shape.

[Solving Means] This technology moves each face in a normal direction of each face from data representing an object shape of a CAD model by discretizing a surface of the CAD model into a grid and arranging faces surrounded by discrete points, to thereby generate an expansion model or a contraction model of the object shape of the CAD model, considers that the surface of the expansion model or the contraction model is uniformly charged and solves a Laplace's equation for an electrostatic field on the surface according to a boundary element method to thereby determine a potential distribution on the surface of the expansion model or the contraction model, and detects a feature part of the object shape on the basis of the determined potential distribution.

### TECHNICAL FIELD

The present invention relates to a processing apparatus, a method of detecting a feature part of a CAD model, and a program for obtaining a computational grid required for numerical analysis of the airframe of an aircraft, for example.

### BACKGROUND ART

In the field of computational dynamics, the key process is a process of dividing a computational domain into finite discrete points, so-called computational grid generation. If the discrete points are not arranged at suitable positions, the result of computation may have a non-physical error. The computational grid is, in other words, meshes throughout an object, and it has to entirely cover the object shape. If it fails to entirely cover the object shape, an unnatural “burr” is produced, which remarkably deteriorates the computation accuracy.

In particular, regarding a part such as a ridge part of the object shape or an intersection part of objects (referred to as “feature part”), if the discrete points are not arranged in the feature part, numerical calculation to represent the feature of the shape cannot be performed.

Conventionally, the feature parts have been checked by eyes for generating a grid to appropriately reproduce the parts. However, since as the model becomes more complex, the time restriction imposed on the human work becomes more severe, it is desirable to automatically detect feature parts.

One of the conventional techniques is a technique of measuring angle and curvature of a surface of the model. In this technique, the object shape is reproduced as a CAD model by arranging numerous small triangular or rectangular faces, for example. Then, angle and curvature between adjacent faces are calculated, and a part the angle and curvature of which are larger than a certain threshold is detected as a feature part.

More specifically, an angle formed by adjacent triangles is calculated on the basis of a unit normal vector of each triangle, for example. That is, in a case where θ as follows is larger than a certain threshold θ_thresh, it is determined as a feature part (see Non-Patent Literature 1).

θ=cos⁻¹(\vec{n}_{left}·\vec{n}_{right})

### CITATION LIST

### Non-Patent Literature

Non-Patent Literature 1: ‘Hexahedra Grid Generation Method for Flow Computation’ a Paulus R. Lahur of Japan Aerospace Exploration Agency, 22nd Applied Aerodynamics Conference and Exhibit, 16-19 Aug. 2004, Providence, R.I.

### DISCLOSURE OF INVENTION

### Technical Problem

Although the above-mentioned technique is simple, some patterns cannot be detected even in a simple example. For example, in a case where θ_thresh=60 degrees is set, a feature part in which two flat faces intersect each other at a small angle, i.e., 30 degrees cannot be detected. It is thus difficult to appropriately detect a feature part only by using a relationship between the adjacent triangles.

In view of the above-mentioned circumstances, it is an object of the present invention to provide a processing apparatus, a method of detecting a feature part of a CAD model, and a program, by which a feature part of an object shape can be appropriately made apparent.

### Solution to Problem

In order to accomplish the above-mentioned object, a processing apparatus according to an embodiment of the present invention includes a feature part detector that moves each face in a normal direction of each face from data representing an object shape of a CAD model by discretizing a surface of the CAD model into a grid and arranging faces surrounded by discrete points, to thereby generate an expansion model or a contraction model of the object shape of the CAD model, considers that the surface of the expansion model or the contraction model is uniformly charged and solves a Laplace's equation for an electrostatic field on the surface according to a boundary element method to thereby determine a potential distribution on the surface of the expansion model or the contraction model, and detects a feature part of the object shape on the basis of the determined potential distribution.

In the present invention, it is possible to emphasize the feature part of the object shape by moving each face in a normal direction of each face surrounded by discrete points to thereby generate the expansion model or the contraction model and solving it in accordance with the Laplace's equation. The feature part can be thus appropriately made apparent.

Here, the data representing the object shape of the CAD model by discretizing the surface of the CAD model into the grid and arranging the faces surrounded by the discrete points may be data of standard triangulated language/standard tessellation language (STL).

A method of detecting a feature part of a CAD model according to an embodiment of the present invention includes: reproducing an object shape of the CAD model by discretizing a surface of the CAD model into a grid and arranging faces surrounded by discrete points; moving each face in a normal direction of each face to thereby generate an expansion model or a contraction model of the object shape of the CAD model; considering that the surface of the expansion model or the contraction model is uniformly charged and solving a Laplace's equation for an electrostatic field on the surface according to a boundary element method to thereby determine a potential distribution on the surface of the expansion model or the contraction model; and detecting the feature part of the object shape on the basis of the determined potential distribution.

A program according to an embodiment of the present invention causes a computer to execute: a step of moving each face in a normal direction of each face from data representing an object shape of a CAD model by discretizing a surface of the CAD model into a grid and arranging faces surrounded by discrete points, to thereby generate an expansion model or a contraction model of the object shape of the CAD model; a step of considering that the surface of the expansion model or the contraction model is uniformly charged and solving a Laplace's equation for an electrostatic field on the surface according to a boundary element method to thereby determine a potential distribution on the surface of the expansion model or the contraction model; and a step of detecting a feature part of the object shape on the basis of the determined potential distribution.

### Advantageous Effects of Invention

According to the present invention, it is possible to appropriately make apparent a feature part of an object shape. Accordingly, the processing of the feature part, which has been conventionally manually performed, is automatized. As a result, processes from grid generation to numerical analysis are automatically performed only by preparing a CAD model. Therefore, the total turnaround for numerical analysis decreases, and troublesome tasks including optimization and the like can be greatly reduced.

### BRIEF DESCRIPTION OF DRAWINGS

FIG. 1 A block diagram showing a configuration of a processing apparatus according to an embodiment of the present invention.

FIG. 2 A perspective view showing the airframe of an aircraft as a CAD model represented by STL data.

FIG. 3 An enlarged diagram of a portion denoted by the reference sign A of FIG. 2.

FIG. 4 An enlarged diagram of a portion denoted by the reference sign B of FIG. 2.

FIG. 5 A diagram showing a triangle represented by the STL data.

FIG. 6 A diagram showing an example of the STL data.

FIG. 7 A flowchart showing a flow of processing in the processing apparatus shown in FIG. 1.

FIG. 8 A diagram showing a state in which a triangle, which is focused one of the triangles shown in FIGS. 2 to 4, is moved in a normal vector direction.

FIG. 9 A diagram showing an expansion model focusing on a protruding portion of the airframe.

FIG. 10 A diagram showing an expansion model focusing on a depressed portion of the airframe.

FIG. 11 A perspective view showing the outer appearance of the CAD model when the feature parts are detected.

FIG. 12 A diagram showing a result when the potential is determined without expansion.

FIG. 13 A diagram showing a result when the potential is determined after expansion.

FIG. 14 A diagram showing a state in which a triangle, which is focused one of the triangles shown in FIGS. 2 to 4, is moved in the normal vector direction to contract to contract.

### MODE(S) FOR CARRYING OUT THE INVENTION

Hereinafter, an embodiment of the present invention will be described with reference to the drawings.

FIG. 1 is a diagram showing a processing apparatus according to the embodiment of the present invention.

As shown in FIG. 1, a processing apparatus 10 includes a data convertor 11, a feature part detector 12, and a numerical analyzer 13. This processing apparatus 10 is typically configured by installing programs that configure the respective blocks into a computer system.

The data convertor 11 converts CAD data into STL data.

Here, the standard triangulated language/standard tessellation language (STL) is one of formats of CAD data representing an arbitrary three-dimensional surface shape as numerous triangles. The STL data according to this embodiment is data representing an object shape of the CAD model by discretizing the surface of the CAD model into a grid and arranging triangles surrounded by discrete points. FIG. 2 shows the airframe shape of an aircraft as the CAD model represented by the STL data. FIGS. 3 and 4 show partially enlarged portions (A and B in FIG. 2).

Such data is data writing, for each triangle, a unit normal vector of the triangle and coordinates of three vertices of the triangle as shown in FIG. 5. An example of the data format is shown in FIG. 6.

The feature part detector 12 moves each triangle in a normal direction of each triangle to thereby generate an expansion model or a contraction model of an object shape of a CAD model, considers that a surface of the expansion model or the contraction model is uniformly charged and solves a Laplace's equation for an electrostatic field on the surface according to a boundary element method to thereby determine a potential distribution on the surface of the expansion model or the contraction model, and detects a feature part of the object shape on the basis of the determined potential distribution.

The numerical analyzer 13 calculates resistance of the surface of the airframe, for example. More specifically, the numerical analyzer 13 generates a computational grid while keeping features of the object by using feature parts detected by the above-mentioned feature part detector 12, performs computational fluid dynamics analysis by using the computational grid to thereby obtain a pressure distribution on the surface of the airframe, and integrates it with respect to the entire surface of the airframe for calculating the resistance.

Next, a specific example of processing of the processing apparatus 10 will be described according to the flowchart shown in FIG. 7.

The data convertor 11 converts the CAD data into the STL data to prepare the STL data (Step 71). It should be noted that in the processing apparatus according to the present invention, the data convertor 11 is unnecessary in a case where the STL data is prepared in advance.

Next, the feature part detector 12 generates an expansion model obtained by enlarging the CAD model (Step 72).

Specifically, for a vertex x(vector)₁ of each of triangles that constitute the object surface, x(vector)ᵢ+sn(vector) is set as a new vertex position.

Here, n(vector) denotes a normal vector of the triangle corresponding to the vertex and s denotes the amount of expansion. The amount of expansion needs to be changed in accordance with each CAD model, and the amount of expansion is desirably about five times as large as the minimum value of the side lengths of all the triangles. Note that it is assumed that the amount of contraction to be described later is approximately equal to it.

FIG. 8 is a diagram showing a state in which one triangle, which is focused one of the triangles shown in FIGS. 2 to 4, is moved in the normal vector direction.

Here, provided that s>0 and n(vector) extends outward from the surface of the airframe, the triangle moves outward from the surface of the airframe in accordance with x(vector)ᵢ+sn(vector).

Here, FIG. 9 shows an expansion model focusing on a protruding portion of the airframe and FIG. 10 shows an expansion model focusing on a depressed portion of the airframe. The protruding portion of the airframe is, for example, an edge portion of a wing shown in FIG. 3. The depressed portion of the airframe is, for example, a boundary between the fuselage and the wing of the airframe shown in FIG. 4.

When the triangles move outward from the surface of the airframe (in the arrow direction in the figure), in the protruding portion of the airframe, triangles T arranged on a surface of an airframe A with no gaps move away from each other in this move such that an expansion model E having gaps G is provided as shown in FIG. 9. In the depressed portion of the airframe, the triangles T arranged on the surface of the airframe A with no gaps approach each other in this move such that an expansion model E having intersections I is provided as shown in FIG. 10.

More specifically seeing the above-mentioned expansion model E, it can be understood that as the protruding and depressed portions become larger, the intersections I and the gaps G become larger.

Next, the feature part detector 12 considers that the surface of the expansion model E is uniformly charged and solves a Laplace's equation for an electrostatic field on the surface according to a boundary element method to thereby determine a potential distribution on the surface of the expansion model E (Step 73).

Hereinafter, the signs will denote the following meanings.

ϕ: electrostatic field

q−∂φ∂n potential
x(vector): position vector indicating surface
n: normal direction of surface
D: analysis domain
∂D: boundary of analysis domain (surface of CAD model)
r: distance between points i and j on surface

It is known that the relationship between the electrostatic field and the potential is governed by the Laplace's equation.

$${∇}^{2} φ = 0 in D or \frac{{\partial }^{2} φ}{\partial {x}^{2}} + \frac{{\partial }^{2} φ}{\partial {y}^{2}} + \frac{{\partial }^{2} φ}{\partial {z}^{2}} = 0 in D \qquad ( 1 )$$

It is assumed that the electrostatic field ϕ (vector) is uniformly distributed on the surface.

φ=φ on ∂D (2)

Using Formula (2) as a boundary condition, Formula (1) can be modified by using a Green's function of the Laplace's equation as follows.

$$\int {\int }_{\partial D} \frac{1}{r} q dS - 2 πφ = \int {\int }_{\partial D} \frac{\partial }{\partial n} ( \frac{1}{r} ) \dot{φ} dS \qquad ( 3 )$$

Formula (3) is a basic formula of the boundary element method, and it is discretized by using the triangle on the surface as the element to thereby determine q.

$${\sum }_{j = 1}^{N} \int {\int }_{\partial {D}_{j}} \frac{1}{{r}_{ij}} q dS - 2 {πφ}_{i} = {\sum }_{j = 1}^{N} \int {\int }_{\partial {D}_{j}} \frac{\partial }{\partial n} {( \frac{1}{r} )}_{ij} \dot{φ} dS \qquad ( 4 )$$

In all the triangles, ϕ takes a constant value. Moreover, provided that q takes a constant value in each triangle (it is equivalent to setting the boundary element as a primary element), Formula (4) can be modified as follows.

$${\sum }_{j = 1}^{N} ( \int {\int }_{\partial {D}_{j}} \frac{1}{{r}_{ij}} dS ) {q}_{j} - 2 π \dot{φ} = \dot{φ} {\sum }_{j = 1}^{N} \int {\int }_{\partial {D}_{j}} \frac{\partial }{\partial n} {( \frac{1}{r} )}_{ij} dS \qquad ( 5 )$$

The following formula is obtained by changing Formula (5) into a matrix form.

$$G \vec{q} = H \vec{φ}$$

$$Here , \\ \begin{matrix}G \vec{q} = H \vec{φ} G = \{ {g}_{ij} \} , {g}_{ij} = \int {\int }_{\partial D} \frac{1}{{r}_{ij}} dS , H = \{ {h}_{ij} \} , {h}_{ij} = 2 {πδ}_{ij} + \int {\int }_{\partial D} \frac{\partial }{\partial n} ( \frac{1}{{r}_{ij}} ) dS & ( 6 )\end{matrix}$$

Formula (6) is simultaneous linear equations regarding the unknown vector q, and q in each triangle is obtained by solving it.

It should be noted that the boundary element method shown above is merely an example, the present invention is not limited thereto, and other boundary element methods may be used as a matter of course.

Next, from the surface potential q (potential distribution) obtained in accordance with the boundary element method, a part the absolute value of which is large is extracted (Step 74). In other words, a feature part of the object shape is detected on the basis of the potential distribution.

The absolute value is considered because the feature part exhibits a negative value with a large absolute value as it is a depressed portion and takes a positive value with a large absolute value as it is a protruding portion. Therefore, |q| not q, is used in order to model both the protruding and depressed portions at the same time.

Here, FIG. 11 is a perspective view showing the outer appearance of the CAD model when the feature part is detected. FIG. 12 shows a result when the potential is determined without expansion and FIG. 13 shows a result when the potential is determined after expansion.

Comparing the result of FIG. 12 with the result of FIG. 13, it can be seen that almost all the feature parts fail to be made apparent in the result when the potential is determined without expansion (FIG. 12) while the protruding and depressed portions are made apparent in the result when the potential is determined after expansion (FIG. 13).

The present invention is not limited to the above-mentioned embodiment and various modifications and applications can be made without departing from the technical concept of the invention. Implementations according to the modifications and applications are also encompassed in the technical scope of the present invention.

For example, although the expansion model is generated by expanding the CAD model in the above-mentioned embodiment, it is also possible to generate a contraction model by contracting the CAD model, consider that the surface of the contraction model is uniformly charged, solve a Laplace's equation for an electrostatic field on the surface according to a boundary element method to thereby determine a potential distribution on the surface of the contraction model, and detect a feature part.

FIG. 14 shows a state in which a triangle, that is focused one of the triangles shown in FIGS. 2 to 4, is moved in the normal vector direction to contract. For example, provided that s<0 and n(vector) extends outward from the surface of the airframe, the triangle moves inward from the surface of the airframe in accordance with x(vector)₁+sn(vector).

Then, by determining the potential after contraction, the feature parts that are the protruding and depressed portions can be made apparent as in the case of expansion.

In addition, although the STL data is used as it is for all pieces of information on the unit normal vector of the triangle and the coordinates of the three vertices of the triangle in the above-mentioned embodiment, the unit normal vector of the triangle can also be calculated in the following steps, for example.

$$\vec{n} = \frac{\vec{r} \times \vec{s}}{\vert \vec{r} \times \vec{s} \vert} , \vec{r} = {\vec{x}}_{2} - {\vec{x}}_{1} , \vec{s} = {\vec{x}}_{3} - {\vec{x}}_{1}$$

Here, “x” denotes the outer product of vectors, and it is a calculation method using the fact that the outer product of r(vector) and s(vector) is perpendicular to both of r(vector) and s(vector).

Therefore, the present invention can be implemented even in a case where the STL data does not include the unit normal vector of the triangle.

Furthermore, although the STL data representing the object shape of the CAD model by arranging the triangles is used in the present embodiment above, the present invention can be implemented also with data representing the object shape of the CAD model by arranging rectangles or a polygon having more sides.

### REFERENCE SIGNS LIST

10 processing apparatus
11 data convertor
12 feature part detector
13 numerical analyzer

1. A processing apparatus, comprising
a feature part detector that
moves each face in a normal direction of each face from data representing an object shape of a CAD model by discretizing a surface of the CAD model into a grid and arranging faces surrounded by discrete points, to thereby generate an expansion model or a contraction model of the object shape of the CAD model,
considers that the surface of the expansion model or the contraction model is uniformly charged and solves a Laplace's equation for an electrostatic field on the surface according to a boundary element method to thereby determine a potential distribution on the surface of the expansion model or the contraction model, and
detects a feature part of the object shape on a basis of the determined potential distribution.

2. The processing apparatus according to claim 1, wherein
the data representing the object shape of the CAD model by discretizing the surface of the CAD model into the grid and arranging the faces surrounded by the discrete points is data of standard triangulated language/standard tessellation language (STL).

3. A method of detecting a feature part of a CAD model, comprising:
reproducing an object shape of the CAD model by discretizing a surface of the CAD model into a grid and arranging faces surrounded by discrete points;
moving each face in a normal direction of each face to thereby generate an expansion model or a contraction model of the object shape of the CAD model;
considering that the surface of the expansion model or the contraction model is uniformly charged and solving a Laplace's equation for an electrostatic field on the surface according to a boundary element method to thereby determine a potential distribution on the surface of the expansion model or the contraction model; and
detecting the feature part of the object shape on a basis of the determined potential distribution.

4. A non-transitory computer readable medium storing a program that causes a computer to execute:
a step of moving each face in a normal direction of each face from data representing an object shape of a CAD model by discretizing a surface of the CAD model into a grid and arranging faces surrounded by discrete points, to thereby generate an expansion model or a contraction model of the object shape of the CAD model;
a step of considering that the surface of the expansion model or the contraction model is uniformly charged and solving a Laplace's equation for an electrostatic field on the surface according to a boundary element method to thereby determine a potential distribution on the surface of the expansion model or the contraction model; and
a step of detecting a feature part of the object shape on a basis of the determined potential distribution.
